(19) United States
(12) Patent Application Publication
(10) Pub. No.: US 2025/0218968 A1
(43) Pub. Date: Jul. 3, 2025

(54) PRINTED CIRCUIT BOARD AND SEMICONDUCTOR PACKAGE INCLUDING THE SAME

(71) Applicant: Samsung Electronics Co., Ltd., Suwon-si (KR)

(72) Inventors: Buwon Kim, Suwon-si (KR); Heewoo An, Suwon-si (KR)

(21) Appl. No.: 18/985,156

(22) Filed: Dec. 18, 2024

(30) Foreign Application Priority Data
Jan. 3, 2024 (KR) 10-2024-0000899

(51) Int. Cl. H01L 23/538; H01L 23/00; H01L 23/31; H01L 25/07; H05K 1/11; H05K 1/18

(52) U.S. Cl. CPC H01L 23/5386; H01L 24/48; H01L 24/49; H01L 25/074; H05K 1/111; H05K 1/181; H01L 23/3128; H01L 2224/48145; H01L 2224/48228; H01L 2224/49112; H01L 2225/06506; H01L 2225/0651; H01L 2225/06562

(57) ABSTRACT

A printed circuit board includes a substrate base, a plurality of substrate wiring patterns on an upper surface and a lower surface of the substrate base, the plurality of substrate wiring patterns including at least one equipotential plane, a plurality of equipotential plating lines, a plurality of signal plating lines, and a plurality of upper connection pads on the upper surface of the substrate base, the at least one equipotential plane including at least one main equipotential plane and a plurality of sub-equipotential planes, a plurality of upper pad layers covering at least portions of the plurality of upper connection pads, and an upper solder resist layer covering a portion of the upper surface of the substrate base and portions of the plurality of substrate wiring patterns, wherein the upper solder resist layer includes a plurality of etchback openings arranged in a column in a first lateral direction.

### CROSS-REFERENCE TO RELATED APPLICATION

This application is based on and claims priority under 35 U.S.C. § 119 to Korean Patent Application No. 10-2024-0000899, filed on Jan. 3, 2024, in the Korean Intellectual Property Office, the disclosure of which is incorporated by reference herein in its entirety.

### BACKGROUND

The inventive concept relates to a printed circuit board (PCB) and a semiconductor package including the same.

As electronic products are required to be miniaturized, multifunctional, and highly efficient, semiconductor chips are becoming more highly integrated and faster. Accordingly, to achieve such advanced semiconductor chips, a PCB with improved reliability and a semiconductor package including the PCB are being developed.

### SUMMARY

The inventive concept provides a printed circuit board (PCB) having improved reliability and a semiconductor package including the same.

According to an aspect of the inventive concept, a PCB includes a substrate base, a plurality of upper wiring patterns on an upper surface of the substrate base, the plurality of upper wiring patterns including a first equipotential plane, a plurality of equipotential plating lines, a plurality of signal plating lines, and a plurality of upper connection pads on the upper surface of the substrate base, the first equipotential plane including at least one main equipotential plane and a plurality of sub-equipotential planes, a plurality of upper pad layers covering at least portions of the plurality of upper connection pads, and an upper solder resist layer covering a portion of the upper surface of the substrate base and portions of the plurality of substrate wiring patterns, wherein the upper solder resist layer includes a plurality of etchback openings arranged in a column in a first lateral direction, bottom portions of the plurality of etchback openings expose portions of the upper surface of the substrate base, and an etchback gap disposed between two etchback openings, which are adjacent to each other in the first lateral direction, and the first equipotential plating line extends through the etchback gap and connects the first main equipotential plane to one of the plurality of sub-equipotential planes.

According to another aspect of the inventive concept, a PCB includes a substrate base having a chip adhesion region and a chip peripheral region surrounding the chip adhesion region, and a plurality of substrate wiring patterns including a first equipotential plane, a plurality of equipotential plating lines, a plurality of signal plating lines, a plurality of upper connection pads on an upper surface of the substrate base, and a plurality of lower connection pads on a lower surface of the substrate base. The first equipotential plane comprising at least one main equipotential plane and a plurality of sub-equipotential planes. The PCB further includes a plurality of via patterns configured to electrically connect the plurality of upper connection pads to the plurality of lower connection pads, the plurality of via patterns passing through at least a portion of the substrate base, a plurality of upper pad layers covering at least portions of the plurality of upper connection pads, and an upper solder resist layer on the plurality of substrate wiring patterns and the upper surface of the substrate base. Portions of the upper surface of the substrate base are exposed by bottom portions of the plurality of etchback openings. At least the portions of the plurality of upper connection pads covered by the plurality of upper pad layers arc disposed at bottom portions of the plurality of upper pad openings. At least one of the plurality of equipotential plating lines extends through an etchback gap and connects the at least one main equipotential plane to one of the plurality of sub-equipotential planes. The plurality of upper connection pads include a first upper connection pad and a plurality of second upper connection pads. One end of each of the plurality of signal plating lines is connected to respective connection pad of the plurality of second upper connection pads. One end of at least one other of the plurality of equipotential plating lines is connected to a first upper connection pad.

According to another aspect of the inventive concept, a semiconductor package includes at least one semiconductor chip on the PCB, the at least one semiconductor chip including a plurality of chip pads, a plurality of bonding wires connected to the plurality of chip pads, and a molding layer covering the PCB and surrounding the at least one semiconductor chip and the plurality of bonding wires, wherein the PCB includes a substrate base having a chip adhesion region to which the at least one semiconductor chip is adhered and a chip peripheral region surrounding the chip adhesion region, a plurality of substrate wiring patterns including a first equipotential plane, a plurality of equipotential plating lines, a plurality of signal plating lines, and a plurality of upper connection pads on an upper surface of the substrate base, the plurality of substrate wiring patterns including a plurality of lower connection pads on a lower surface of the substrate base, and the first equipotential plane including a first main equipotential plane and a plurality of sub-equipotential planes, a plurality of upper pad layers covering at least portions of the plurality of upper connection pads and connected to the plurality of bonding wires, and an upper solder resist layer on the plurality of substrate wiring patterns and the upper surface of the substrate base, wherein the upper solder resist layer includes a plurality of etchback openings arranged in a column in a first lateral direction and a plurality of upper pad openings arranged in a column in the first lateral direction, portions of the upper surface of the substrate base are exposed by bottom portions of the plurality of etchback openings, and at least the portions of the plurality of upper connection pads covered by the plurality of upper pad layers are disposed at bottom portions of the plurality of upper pad openings, and at least one of the plurality of equipotential plating lines extends along an etchback gap, and connects the first main equipotential plane and one of the plurality of sub-equipotential planes, which are adjacent to opposite ends of the etchback gap in a second lateral direction, wherein the second lateral direction is perpendicular to the first lateral direction, and the plurality of etchback openings are filled by the molding layer.

### BRIEF DESCRIPTION OF THE DRAWINGS

Embodiments will be more clearly understood from the following detailed description taken in conjunction with the accompanying drawings in which:

FIG. 1A is a cross-sectional view of a semiconductor package according to embodiments;

FIG. 1B is a plan view of an upper surface of a printed circuit board (PCB) included in the semiconductor package shown in FIG. 1A;

FIGS. 2A to 2C are plan views of a portion of an upper surface of a PCB included in a semiconductor package, according to embodiments;

FIGS. 3 to 6 are plan views of a method of manufacturing a PCB, according to an embodiment;

FIGS. 7A to 7D are cross-sectional views of a method of manufacturing a semiconductor package, according to an embodiment; and

FIG. 8 is a cross-sectional view of a semiconductor package according to embodiments.

### DETAILED DESCRIPTION OF THE EMBODIMENTS

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

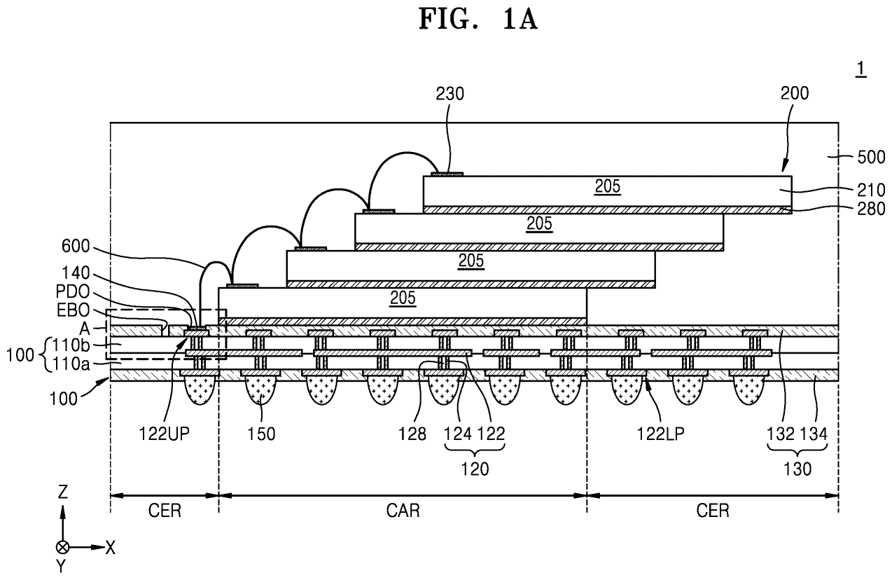

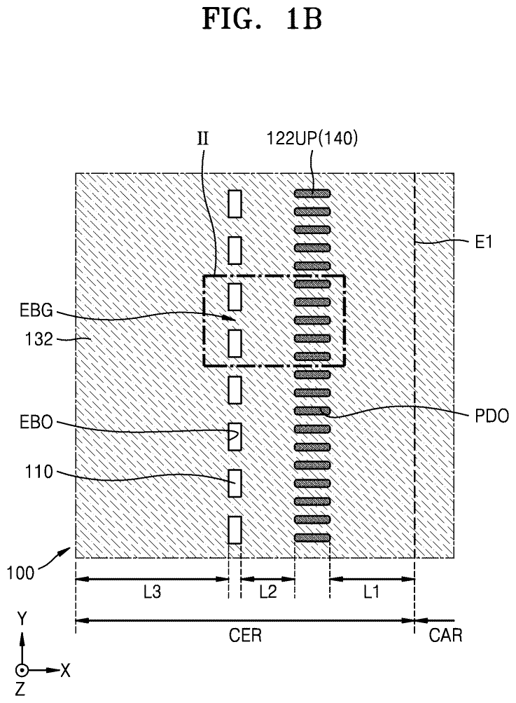

FIG. 1A is a cross-sectional view of a semiconductor package according to embodiments, and FIG. 1B is a plan view of an upper surface of a printed circuit board (PCB) included in the semiconductor package. FIG. 1B is a plan view of portion A of the PCB 100 in FIG. 1A.

Referring to FIG. 1A, a semiconductor package 1 may include a PCB 100, a plurality of semiconductor chips 200, and a molding layer 500. The plurality of semiconductor chips 200 may be adhered onto the PCB 100. The molding layer 500 may surround the plurality of semiconductor chips 200 on the PCB 100. The PCB 100 may have a chip adhesion region CAR and a chip peripheral region CER surrounding the chip adhesion region CAR. A lowermost one of the plurality of semiconductor chips 200 may be adhered onto the chip adhesion region CAR.

For example, the PCB 100 may include a double-sided PCB or a multi-layered PCB. The PCB 100 may include at least one substrate base 110 and a substrate wiring structure 120.

The substrate base 110 may include at least one material selected from a phenol resin, an epoxy resin, and polyimide. For example, the substrate base 110 may include at least one material selected from Flame Retardant 4 (RF-4), tetrafunctional epoxy, polyphenylene ether, epoxy/polyphenylene oxide, bismaleimide triazine (BT), Thermount, cyanate ester, polyimide, and a liquid crystal polymer.

In some embodiments, the PCB 100 may include substrate base 110 that includes a plurality of substrate base layers (e.g., 110a, 110b) that are stacked. When the PCB 100 includes the plurality of substrate base layers that are stacked, the substrate base 110 may include a core layer and at least one prepreg layer stacked on each of an upper surface and a lower surface of the core layer. In some embodiments, each of the core layer and the at least one prepreg layer may include the same material. A thickness of the at least one prepreg layer may be less than a thickness of the core layer. However, in some cases where the substrate base 110 includes a plurality of substrate base layers, each substrate base layer may include the same material and have the same thickness as other substrate base layers, and there may be two or more substrate base layers.

It should be noted that items described in the singular herein, may be provided in plural, as can be seen in the various figures from the context in which they are described. Further, as used herein, a substrate base 110 or a plurality of substrate base layers may refer to a composite layer of substrate base layers included in the PCB 100. For example, the substrate base 110 may refer to one substrate base layer when the substrate base 110 includes the one substrate base layer, and may refer to a composite layer of at least two substrate base layers when the substrate base 110 includes the at least two substrate base layers that are stacked. Also, upper surfaces and lower surfaces of the substrate base 110 may refer to an upper surface that contacts an upper solder resist layer 132 and a lower surface that contacts a lower solder resist layer 134.

A substrate wiring structure 120 may include a plurality of substrate wiring patterns 122 and a plurality of substrate via patterns 124. The plurality of substrate wiring patterns 122 may be on an upper surface and a lower surface of the substrate base 110 or inside the substrate base 110 and extend in a lateral direction (i.e., X-direction or Y-direction). The plurality of substrate via patterns 124 may extend in a vertical direction (i.e., Z-direction) and pass through at least a portion of the substrate base 110. Each of the plurality of substrate via patterns 124 may electrically connect a corresponding set of two substrate wiring patterns 122 located at different vertical levels, from among the plurality of substrate wiring patterns 122. In some embodiments, the PCB 100 may include a plurality of substrate base layers that are stacked, and a substrate wiring pattern of the plurality of substrate wiring patterns 122 may be on the upper surface and the lower surface of each substrate base layer of the plurality of substrate base layers. For example, some of the plurality of substrate wiring patterns 122 may be between two substrate base layers, which are adjacent to each other in the vertical direction, among the plurality of substrate base layers. A wiring pattern may refer to a group of wiring structures at the same vertical layer formed through a patterning process, or may refer to a single one of those wiring structures.

The substrate wiring structure 120 may include or be formed of copper (Cu) or an alloy including copper (Cu). Each of the plurality of substrate wiring patterns 122 may include or be formed of electrolytically deposited (ED) copper foils, rolled-annealed (RA) copper foils, ultra-thin copper foils, sputtered copper, or copper alloys. Each of the plurality of substrate via patterns 124 may be formed to fill at least a portion of a via through hole passing through at least one substrate base layer of the substrate base 110. For example, the substrate via pattern 124 may include or be formed of copper, nickel, stainless steel, or beryllium copper. In some embodiments, the substrate via pattern 124 may cover an inner sidewall of the via through hole passing through a substrate base layer of the substrate base 110 without completely filling the via through hole, and a via filling insulating layer 128 may cover the substrate via pattern 124 and fill the via through hole. For example, the via through hole may be completely filled by the substrate via pattern 124 and the via filling insulating layer 128.

The PCB 100 may further include solder resist layers 130 covering the upper surface and the lower surface of the substrate base 110. The solder resist layers 130 may include or be formed of an upper solder resist layer 132 covering the upper surface of the substrate base 110 and a lower solder resist layer 134 covering the lower surface of the substrate base 110.

Some of the substrate wiring patterns 122 on the upper surface of the substrate base 110 may be or include a plurality of upper connection pads 122UP. For example, some of uppermost ones of the substrate wiring patterns 122, which are at a highest vertical level, may be the plurality of upper connection pads 122UP. From among the plurality of substrate wiring patterns 122, the uppermost ones of the substrate wiring patterns 122, which are on the upper surface of the substrate base 110 and at a highest vertical level, may be referred to as upper wiring patterns. The upper solder resist layer 132 may cover side surfaces of the upper wiring patterns. The upper solder resist layer 132 may not cover a portion of upper wiring patterns. In some embodiments, the upper solder resist layer 132 may not cover at least portion of an upper surface of each of the plurality of upper connection pads 122UP. The upper solder resist layer 132 may cover a portion of the upper surface of the substrate base 110. For example, the upper solder resist layer 132 may partially cover a portion of the upper surface of each of the plurality of upper connection pads 122UP. The upper solder resist layer 132 may not cover and expose the remaining portions of the upper surface of each of the plurality of upper connection pads 122UP.

The upper solder resist layer 132 may include a plurality of upper pad openings PDO and a plurality of etchback openings EBO. In some embodiments of the invention, the plurality of upper connection pads 122UP may be located on and exposed by bottom portions of the plurality of upper pad openings PDO. In some embodiments of the invention, a portion of the substrate base 110 may be exposed by a bottom portion of each of the plurality of etchback openings EBO, and the exposed portion of the substrate base 110 may correspond to a region referred to as “etchback regions.”

Some of the substrate wiring patterns 122 located on the lower surface of the substrate base 110 may be or include a plurality of lower connection pads 122LP. For example, some of lowermost ones of the substrate wiring patterns 122, which are at a lowest vertical level, may be the plurality of lower connection pads 122LP. From among the plurality of substrate wiring patterns 122, the substrate wiring patterns 122, which are on the lower surface of the substrate base 110 and at a lowest vertical level, may be referred to as lower wiring patterns. The lower solder resist layer 134 may cover side surfaces of the lower wiring patterns. The lower solder resist layer 134 may not cover a portion of lower wiring patterns. In some embodiments, the lower solder resist layer 134 may not cover at least a portion of an upper surface of each of the plurality of lower connection pads 122LP. The lower solder resist layer 134 may cover a portion of the lower surface of the substrate base 110. For example, the lower solder resist layer 134 may partially cover a portion of a lower surface of each of the plurality of lower connection pads 122LP. The lower solder resist layer 134 may not cover and expose the remaining portions of the lower surface of each of the plurality of lower connection pads 122LP.

A plurality of package connection terminals 150 may be adhered to a lower surface of the PCB 100. The plurality of package connection terminals 150 may be respectively adhered to the plurality of lower connection pads 122LP. In some embodiments, the plurality of package connection terminals 150 may completely cover at least portions of surfaces (e.g., the lower surfaces) of the plurality of lower connection pads 122LP, which are not covered by the lower solder resist layer 134. The plurality of package connection terminals 150 may have a height of about 80 μm or more. For example, the package connection terminal 150 may have a height of about 80 μm to about 350 μm. The package connection terminal 150 may have a lateral width of about 80 μm or more. For example, the package connection terminal 150 may have a lateral width of about 80 μm to about 350 μm. A distance between two adjacent ones of the plurality of package connection terminals 150 may be equal to or greater than the lateral width of the package connection terminal 150. For example, a distance between two adjacent ones of the plurality of package connection terminals 150 may be in a range of about 80 μm to about 500 μm.

The substrate wiring structure 120 including the plurality of substrate wiring patterns 122 and the plurality of substrate via patterns 124 may electrically connect the plurality of upper connection pads 122UP to the plurality of lower connection pads 122LP.

A plurality of upper pad layers 140 may be respectively formed on the plurality of upper connection pads 122UP. The plurality of upper pad layers 140 may cover the plurality of upper connection pads 122UP and fill at least portions of the plurality of upper pad openings PDO. Each of the plurality of upper pad layers 140 may include or be formed of a metal, such as nickel (Ni), gold (Au), and copper (Cu). In some embodiments, each of the plurality of upper pad layers 140 may include a composite layer including a first layer including nickel (Ni) and a second layer including gold (Au). A plurality of bonding wires 600 may be respectively connected to the plurality of upper pad layers 140. The plurality of bonding wires 600 may be electrically and respectively connected to the plurality of upper connection pads 122UP through the plurality of upper pad layers 140.

The plurality of semiconductor chips 200 may be sequentially stacked on the PCB 100 in a vertical direction (Z-direction). Each of the plurality of semiconductor chips 200 may have a rectangular planar shape. A planar shape of the chip adhesion region CAR may substantially be the same as a planar shape of each of the plurality of semiconductor chips 200. For example, the chip adhesion region CAR may have a rectangular planar shape. In some embodiments, the plurality of semiconductor chips 200 may be stacked in a staircase manner at intervals in a lateral direction (X-direction or Y-direction). For example, the lowermost one of the plurality of semiconductor chips 200 may be aligned with the chip adhesion region CAR in the vertical direction (Z-direction). In some embodiments, the plurality of semiconductor chips 200 may be stacked in a staircase manner at intervals in a direction along one side of a rectangular planar shape of at least one of the semiconductor chips. In some embodiments, the plurality of semiconductor chips 200 may be stacked at intervals in a direction (i.e., X-direction or Y-direction) along a diagonal line of a rectangular planar shape of at least one of the semiconductor chips. In some embodiments, some of the plurality of semiconductor chips 200 may be stacked in a staircase manner at intervals in one direction, and some others of the plurality of semiconductor chips 200 may be stacked on the some semiconductor chips 200 in a staircase manner at intervals in a direction opposite to the one direction. In some embodiments, the plurality of semiconductor chips 200 may be stacked and aligned with each other in the vertical direction (Z-direction). For example, each of the plurality of semiconductor chips 200 may be aligned with the chip adhesion region CAR in the vertical direction (Z-direction).

Each of the plurality of semiconductor chips 200 may include a semiconductor substrate 210. The semiconductor substrate 210 may include a semiconductor material, such as a Group IV semiconductor material, a Group III-V semiconductor material, a Group II-VI semiconductor material, or a Group II-VI oxide semiconductor material. For example, the semiconductor substrate 210 may include silicon (Si). Alternatively, the semiconductor substrate 210 may include a semiconductor element, such as germanium (Ge) or a compound semiconductor, such as silicon carbide (SiC), gallium arsenide (GaAs), indium arsenide (InAs), and indium phosphide (InP). Alternatively, the semiconductor substrate 210 may have a silicon on insulator (SOI) structure. For example, the semiconductor substrate 210 may include a buried oxide (BOX) layer. The semiconductor substrate 210 may include a conductive region, for example, a doped well. The semiconductor substrate 210 may have various device isolation structures, such as a shallow trench isolation (STI) structure. The semiconductor substrate 210 may have an active surface and an inactive surface opposite to the active surface.

In the semiconductor chip 200, a semiconductor device 205 including a plurality of individual devices of various types may be formed on the active surface of the semiconductor substrate 210. The plurality of individual devices may include various microelectronic devices, for example, metal-oxide-semiconductor field effect transistors (MOSFETs) (e.g., complementary metal-insulator-semiconductor (CMOS) transistors), system large-scale integration (LSI), image sensors (e.g., CMOS imaging sensor (CIS)), micro-electro-mechanical system (MEMS), active devices, and passive devices. The plurality of individual devices may be electrically connected to the conductive region of the semiconductor substrate 210. The semiconductor device 205 may further include a conductive wiring or a conductive plug configured to electrically connect at least two of the plurality of individual devices or to electrically connect the plurality of individual devices to the conductive region of the semiconductor substrate 210. Also, each of the plurality of individual devices may be electrically isolated from other individual devices adjacent thereto by an insulating film.

The semiconductor device 205 may include a memory semiconductor device. For example, the semiconductor chip 200 may include a memory semiconductor chip. In some embodiments, the memory semiconductor device may be a non-volatile memory semiconductor device, such as flash memory, phase-change random access memory (PRAM), magnetoresistive RAM (MRAM), ferroelectric RAM (FeRAM), or resistive RAM (RRAM). The flash memory may be, for example, V-NAND flash memory. In some other embodiments, the memory semiconductor device may be a volatile memory semiconductor chip, such as dynamic RAM (DRAM) or static RAM (SRAM).

Each of the plurality of semiconductor chips 200 may include a plurality of chip pads 230 located on an upper surface of the corresponding one of the plurality of semiconductor chips 200. For example, the plurality of chip pads 230 may be on an active surface of each of the plurality of semiconductor chips 200. Each of the plurality of semiconductor chips 200 may be stacked on the PCB 100 such that the active surface of each of the plurality of semiconductor chips 200 faces upward (i.e., in a direction away from the PCB 100). Each of the plurality of semiconductor chips 200 may be stacked on the PCB 100 such that the inactive surface of the semiconductor substrate 210 faces downward (i.e., toward the PCB 100).

The plurality of bonding wires 600 may be connected between the plurality of chip pads 230 and the plurality of upper pad layers 140 covering the plurality of upper connection pads 122UP. The plurality of semiconductor chips 200 may be electrically connected to the PCB 100 through the plurality of bonding wires 600. In some embodiments, after the plurality of chip pads 230 of each of the semiconductor chips 200 are sequentially connected from the plurality of chip pads 230 of an uppermost one of the semiconductor chips 200 to the plurality of chip pads 230 of the lowermost one of the semiconductor chips 200, the plurality of bonding wires 600 may connect the plurality of chip pads 230 of the lowermost one of the semiconductor chips 200 to the plurality of upper pad layers 140 covering the plurality of upper connection pads 122UP. In some other embodiments, the plurality of bonding wires 600 may respectively connect the plurality of chip pads 230 of each of the plurality of semiconductor chips 200 to the plurality of upper pad layers 140 covering the plurality of upper connection pads 122UP.

The plurality of semiconductor chips 200 may be respectively adhered onto lower structures with a plurality of die-bonding films 280 adhered to lower surfaces of the semiconductor chips 200 therebetween. For example, a lowermost one of the plurality of semiconductor chips 200 may be adhered onto the chip adhesion region CAR of the PCB 100 with the die-bonding film 280 therebetween, and each of other semiconductor chips 200 may be adhered onto another semiconductor chip 200 located thereunder with the die-bonding film 280 therebetween. The die-bonding film 280 may include, for example, an inorganic adhesive or a polymer adhesive. The polymer adhesive may include, for example, a thermosetting resin (or thermosetting polymer) or a thermoplastic resin (or a thermoplastic polymer). The thermosetting resin may have a three-dimensional cross-linked structure after a monomer is molded by heating. Also, the thermosetting resin may not soften even when reheated. In contrast, the thermoplastic resin may be a resin that exhibits plasticity by heating and has a linear polymer structure. In addition, the polymer adhesive may be of a hybrid type prepared by mixing the thermosetting resin and the thermoplastic resin.

The molding layer 500 covering an upper surface of the PCB 100 and surrounding the plurality of semiconductor chips 200 and the plurality of bonding wires 600 may be on the PCB 100. The molding layer 500 may be, for example, a molding member including an epoxy mold compound (EMC). The molding layer 500 may fill the plurality of etchback openings EBO. The molding layer 500 may fill the plurality of etchback openings EBO and cover portions of the substrate base 110 which are exposed by the bottom portion of the etchback opening EBO. When the plurality of upper pad layers 140 do not entirely fill the plurality of upper pad openings PDO, the molding layer 500 may fill the plurality of upper pad openings PDO. The molding layer 500 may fill the plurality of upper pad openings PDO, surround the plurality of bonding wires 600, and cover the plurality of upper pad layers 140.

Referring to FIGS. 1A and 1B together, the PCB 100 may include the upper solder resist layer 132 covering the upper surface of the substrate base 110. The upper solder resist layer 132 may include the plurality of upper pad openings PDO and the plurality of etchback openings EBO. In some embodiments of the invention, the plurality of upper connection pads 122UP may be disposed at the bottom portions of the plurality of upper pad openings PDO. The plurality of upper pad layers 140 may be on the plurality of upper connection pads 122UP. The plurality of upper pad layers 140 may fill at least portions of the plurality of upper pad openings PDO. A portion of the substrate base 110 may be exposed by the bottom portion of each of the plurality of etchback openings EBO.

Each of the plurality of upper connection pads 122UP may be connected to the substrate via pattern 124. The substrate via pattern 124 may be connected to a lower surface of each of the plurality of upper connection pads 122UP. The plurality of semiconductor chips 200 may be electrically connected to the plurality of upper connection pads 122UP through the plurality of bonding wires 600, respectively. The plurality of upper connection pads 122UP may be electrically connected to the substrate via patterns 124, which are respectively in contact with the lower surfaces of the plurality of upper connection pads 122UP and thus, be electrically connected to the plurality of lower connection pads 122LP.

The plurality of upper connection pads 122UP and the plurality of upper pad layers 140 may be arranged in a column along an edge El of the chip adhesion region CAR. FIG. 1B illustrates an example in which the plurality of upper connection pads 122UP and the plurality of upper pad layers 140 are apart from the edge El of the chip adhesion region CAR in a first lateral direction (X-direction) and are arranged in a column in a second lateral direction (Y-direction), which is perpendicular to the first lateral direction (X-direction), but the inventive concept is not limited thereto. FIG. 1B illustrates only some of the plurality of upper connection pads 122UP and some of the plurality of upper pad layers 140 that are included in the PCB 100. In an embodiment, the chip adhesion region CAR may have a rectangular planar shape, and some of the plurality of upper connection pads 122UP and some of the plurality of upper pad layers 140 may be disposed along four edges of the rectangular planar shape of the chip adhesion region CAR. For example, the chip adhesion region CAR may have other edges extending in the first lateral direction (X-direction) or a portion extending in the second lateral direction (Y-direction) in the PCB 100. The upper connection pads 122UP and the upper pad layers 140 may be additionally disposed adjacent to and along the other edges of the edge of the chip adhesion region CAR, and may be apart from the other edge of the chip adhesion region CAR. In an embodiment, the upper connection pads 122UP and the upper pad layers 140 may be arranged in column in the first lateral direction (for example Y-direction) in the PCB 100, and may be apart from one of the other edge of the chip adhesion region CAR in the first lateral direction (for example X-direction).

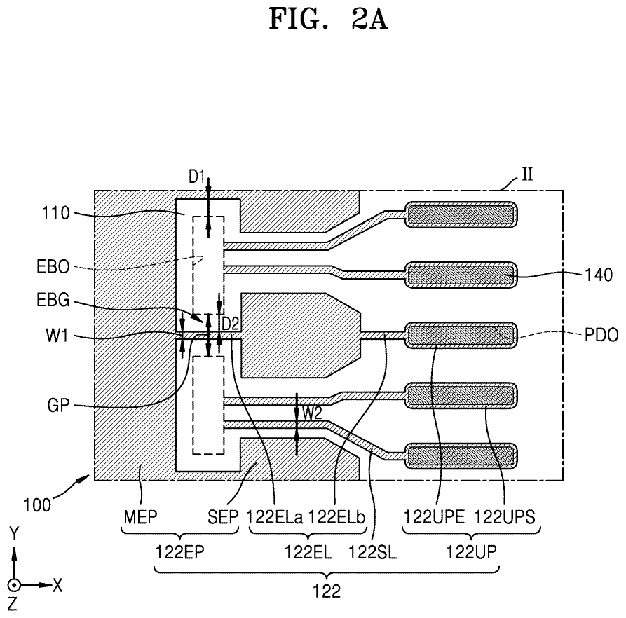

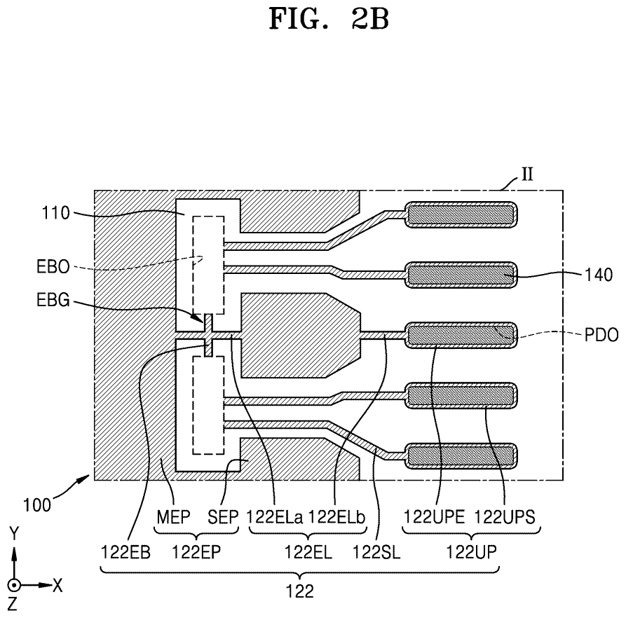

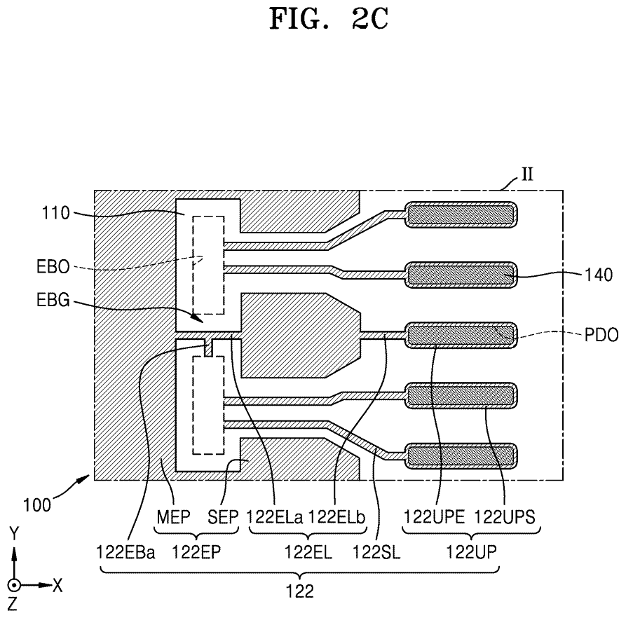

The plurality of etchback openings EBO may be arranged in a column between the edge of the chip adhesion region CAR and an edge of the PCB 100. An etchback gap EBG may be defined as an area between each pair of two etchback openings EBO, which are adjacent to each other in a direction of the column (e.g., Y-direction in FIG. 2A). A portion of the substrate base 110 located in the etchback gap EBG may be covered by the upper solder resist layer 132. The plurality of etchback openings EBO may be apart from the plurality of upper connection pads 122UP. For example, the plurality of etchback openings EBO may be arranged in a column between a column formed by the plurality of upper connection pads 122UP and the edge of the PCB 100. The number of etchback openings EBO may be equal to or less than the number of upper connection pads 122UP and the number of upper pad layers 140.

The plurality of upper connection pads 122UP and the plurality of upper pad layers 140 may be a first separation distance L1 apart from the edge E1 of the chip adhesion region CAR in a lateral direction (i.e. X-direction). and may be a second separation distance L2 apart from the plurality of etchback openings EBO in the lateral direction. The plurality of etchback openings EBO may be a third separation distance L3 apart from the edge of the PCB 100 (i.e., an edge of the substrate base 110). The second separation distance L2 may be equal to or greater than the first separation distance L1, and the third separation distance L3 may be greater than each of the first separation distance L1 and the second separation distance L2. For example, the first separation distance L1 may be in a range of about 400 μm to about 600 μm, the second separation distance L2 may be in a range of about 100 μm to about 600 μm, and the third separation distance L3 may be in a range of about 800 μm to about 1200 μm.

FIGS. 2A to 2C are plan views of a portion of an upper surface of a PCB included in a semiconductor package, according to embodiments. Specifically, FIGS. 2A to 2C are plan views of portion II of FIG. 1B from which the upper solder resist layer 132 is omitted.

Referring to FIGS. 1B and 2A together, the PCB 100 may include substrate wiring patterns 122 located on an upper surface of a substrate base 110. Upper wiring patterns, which are uppermost ones of the substrate wiring patterns 122, may be disposed on the upper surface of the substrate base 110 and at a highest vertical level of the substrate wiring patterns 122, The upper wiring patterns may include a plurality of equipotential planes 122EP (in the drawings, for the purpose of simplicity, only one of the equipotential planes 122EP is depicted), a plurality of equipotential plating lines 122EL, a plurality of signal plating lines 122SL, and a plurality of upper connection pads 122UP. For each equipotential plane 122EP, the equipotential plane 122EP, a plurality of equipotential plating lines 122EL, and part of a plurality of upper connection pads 122UP may be integrally connected to each other. The plurality of upper connection pads 122UP may include a plurality of upper signal pads 122UPS and at least one upper equipotential pad 122UPE integrally connected to the equipotential plane 122EP and the plurality of equipotential plating lines 122EL. The plurality of equipotential planes 122EP may be a plurality of power potential planes or a plurality of ground potential planes. An equipotential, such as a power potential or a ground potential, may be provided to (or from) the upper equipotential pad 122UPE, during the operation of the semiconductor package 1. Accordingly, the equipotential planes 122EP, the equipotential plating lines 122EL, the upper equipotential pads 122UPE, which are integrally connected to each other, may be maintained at the same potential (i.e., voltage), during the operation of the semiconductor package 1. The plurality of upper signal pads 122UPS may be formed at the same vertical level and in the same process as the equipotential planes 122EP, the equipotential plating lines 122EL, the upper equipotential pads 122UPE.

A plurality of upper pad layers 140 may be on the plurality of upper connection pads 122UP. The plurality of upper pad layers 140 may fill at least portions of a plurality of upper pad openings PDO. In a view from above, the upper pad layer 140 and the upper pad opening PDO may have the same area, the same location and the same shape. The upper pad layer 140 and the upper pad opening PDO may overlap each other in a vertical direction (Z-direction).

Each equipotential plane 122EP may include at least one main equipotential plane MEP and a plurality of sub-equipotential planes SEP. The main equipotential plane MEP and the sub-equipotential plane SEP may be connected to each other by the equipotential plating lines 122EL. In some embodiments, the main equipotential plane MEP may be connected to two sub-equipotential planes SEP through the plurality of equipotential plating lines 122EL.

Each connection pad of a first set of the plurality of upper connection pads 122UP may be connected to one of the plurality of signal plating lines 122SL. Each connection pad of a second set of the plurality of upper connection pads 122UP may be connected to a respective one of the plurality of equipotential plating lines 122EL. The equipotential plane 122EP may be connected to the upper equipotential pads 122UPE through the equipotential plating lines 122EL. The signal plating lines 122SL may be connected to the upper signal pads 122UPS. For each equipotential plating line 122EL, one end of the equipotential plating line 122EL may be connected to a respective upper equipotential pad 122UPE, and another end of the equipotential plating line 122EL may be connected to the equipotential plane 122EP. FIG. 2A illustrates a case in which one end of the equipotential plating line 122EL is connected to the upper equipotential pad 122UPE and another end of the equipotential plating line 122EL is connected to the sub-equipotential plane SEP, but the inventive concept is not limited thereto. For example, one end of the equipotential plating line 122EL may be connected to the upper equipotential pad 122UPE, and another end of the equipotential plating line 122EL may be connected to the main equipotential plane MEP. Although one end of the signal plating line 122SL is connected to the upper signal pad 122UPS, the other end of the signal plating line 122SL may not be connected to the equipotential plating line 122EL. The other end of the signal plating line 122SL may be located at an edge of the etchback opening EBO. The other end of the signal plating line 122SL may be in contact with the molding layer (refer to 500 in FIG. 1A) filling the etchback opening EBO. The plurality of equipotential plating lines 122EL may include a first equipotential plating line 122ELa and a second equipotential plating line 122Elb. The main equipotential plane MEP may be connected to the upper equipotential pad 122UPE through the sub-equipotential plane SEP, the first equipotential plating line 122ELa and the second equipotential plating line 122Elb. The first equipotential plating line 122ELa may contact and connect the upper equipotential pad 122UPE to the sub-equipotential plane SEP. The second equipotential plating line 122Elb may contact and connect the sub-equipotential plane SEP to the upper equipotential pad 122UPE.

The equipotential plating line 122EL configured to connect the main equipotential plane MEP to the sub-equipotential plane SEP may extend through the etchback gap EBG. The main equipotential plane MEP and the sub-equipotential plane SEP may be respectively adjacent to both ends of the etchback gap EBG that is defined as an area between each pair of two etchback openings EBO, which are adjacent to each other in Y-direction. For example, among both ends of the etchback gap EBG in a first lateral direction (X-direction), the main equipotential plane MEP may be adjacent to one end of the etchback gap EBG, and the sub-equipotential plane SEP may be adjacent to the other end of the etchback gap EBG. The main equipotential plane MEP and the sub-equipotential plane SEP may be arranged for the etchback gap EBG to intervene therebetween, and may be connected to each other by the equipotential plating line 122EL extending through the etchback gap EBG.

The substrate wiring pattern 122, which is adjacent to the etchback opening EBO and on the upper surface of the substrate base 110, may be a first distance D1 apart from the etchback opening EBO in a lateral direction. The equipotential plating line 122EL extending through the etchback gap EBG may be a second distance D2 apart from each of two etchback openings EBO defining the etchback gap EBG in the lateral direction. The first distance D1 may be equal to or greater than the second distance D2. For example, the second distance D2 may be in a range of about 30 μm to about 60 μm, and the first distance D1 may be in a range of about 30 μm to about 80 μm. The equipotential plating line 122EL may extend to have a first lateral width W1, and the signal plating line 122SL may extend to have a second lateral width W2. Each of the first lateral width W1 and the second lateral width W2 may be less than each of the first distance D1 and the second distance D2. The first lateral width W1 may substantially be equal to the second lateral width W2. For example, each of the first lateral width W1 and the second lateral width W2 may be in a range of about 20 μm to about 40 μm. A gap width GP of the etchback gap EBG defined between two etchback openings EBO, which are adjacent to each other in the direction of the column, may be greater than 3 times each of the first lateral width W1 and the second lateral width W2 and less than five times each of the first lateral width W1 and the second lateral width W2. For example, the gap width GP of the etchback gap EBG may be in a range of about 80 μm to about 160 μm.

The etchback opening EBO may have a rectangular planar shape. Each of the plurality of etchback openings EBO may have a major axis in a direction of a column (e.g., the second lateral direction (Y-direction)) and have a minor axis in a direction (e.g., the first lateral direction (X-direction)), which is perpendicular to the direction of the column. For example, a lateral width of each of the plurality of etchback openings EBO in a minor axis direction may be in a range of about 130 μm to about 150 μm. The plurality of etchback openings EBO may have the same lateral width in a major axis direction, without being limited thereto. For example, a lateral width of some of the plurality of etchback openings EBO in the major axis direction may be greater than a lateral width of others of the plurality of etchback openings EBO in the major axis direction.

FIG. 2A illustrates an example in which end portions of the other ends of two signal plating lines 122SL are in contact with one etchback opening EBO, but the inventive concept is not limited thereto. For example, an end portion of the other end of one signal plating line 122SL or end portions of the other ends of at least three signal plating lines 122SL may be in contact with one etchback opening EBO. For example, the number of end portions of the other ends of signal plating lines 122SL in contact with some of the plurality of etchback openings EBO may be different from the number of end portions of the other ends of signal plating lines 122SL in contact with some others of the plurality of etchback openings EBO. End portions of signal plating lines 122SL that are described as being “in contact with” any etchback opening EBO either terminate at or terminate within the etchback opening EBO.

Referring to FIGS. 1B and 2B together, a PCB 100 may include substrate wiring patterns 122 located on an upper surface of the substrate base 110. Upper wiring patterns, which are uppermost ones of the substrate wiring patterns 122 that are on the upper surface of the substrate base 110 and at a highest vertical level, may include a plurality of equipotential planes 122EP (one of which is depicted in FIG. 2B), and associated with each equipotential plane 122EP, a plurality of equipotential extension plating lines 122EB, a plurality of equipotential plating lines 122EL, a plurality of signal plating lines 122SL, and a plurality of upper connection pads 122UP. The equipotential plane 122EP, the plurality of equipotential extension plating lines 122EB, the plurality of equipotential plating lines 122EL, and the plurality of upper connection pads 122UP may be integrally connected to each other. The plurality of upper connection pads 122UP may include a plurality of upper signal pads 122UPS and at least one upper equipotential pad 122UPE.

A plurality of upper pad layers 140 may be on the plurality of upper connection pads 122UP. The plurality of upper pad layers 140 may fill at least portions of a plurality of upper pad openings PDO. In a view from above, the upper pad layer 140 and the upper pad opening PDO may have the same area, the same position and the same shape. The upper pad layer 140 may overlap the upper pad opening PDO in a vertical direction (Z-direction).

Each equipotential plane 122EP may include at least one main equipotential plane MEP and a plurality of sub-equipotential planes SEP. The main equipotential plane MEP and each sub-equipotential plane SEP may be connected to each other by the equipotential plating line 122EL. In some embodiments, the main equipotential plane MEP may be connected to at least two sub-equipotential planes SEP through at least two respective equipotential plating lines 122EL. In addition, at least two equipotential plating lines 122EL may be connected to each sub-equipotential plane SEP. The main equipotential plane MEP may be connected to one of the at least two equipotential plating lines 122EL connected to the sub-equipotential plane SEP, and the upper equipotential pad 122UPE may be connected to the other equipotential plating line 122EL.

Each upper connection pad 122UP of a first set of the plurality of upper connection pads 122UP each may be connected to a respective one of the plurality of signal plating lines 122SL. Each upper connection pad 122UP of a second set of the plurality of upper connection pads 122UP may be connected to a respective one of the plurality of equipotential plating lines 122EL. The equipotential plane 122EP may be connected to the upper equipotential pad 122UPE through the equipotential plating line 122EL. The signal plating line 122SL may be connected to the upper signal pad 122UPS. One end of the equipotential plating line 122EL may be connected to the upper equipotential pad 122UPE, and the other end of the equipotential plating line 122EL may be connected to the equipotential plane 122EP. FIG. 2B illustrates a case in which one end of the equipotential plating line 122EL is connected to the upper equipotential pad 122UPE and the other end of the equipotential plating line 122EL is connected to the sub-equipotential plane SEP, but the inventive concept is not limited thereto. For example, one end of the equipotential plating line 122EL may be connected to the upper equipotential pad 122UPE, and the other end of the equipotential plating line 122EL may be connected to the main equipotential plane MEP. Although one end of the signal plating line 122SL is connected to the upper signal pad 122UPS, the other end of the signal plating line 122SL may not be connected to the equipotential plating line 122EL. The other end of the signal plating line 122SL may be at an edge of the etchback opening EBO. The other end of the signal plating line 122SL may be in contact with the molding layer (refer to 500 in FIG. 1A) filling the etchback opening EBO.

The main equipotential plane MEP and a sub-equipotential plane SEP may be respectively adjacent to both ends of an etchback gap EBG that is defined as an area between each pair of two etchback openings EBO, which are adjacent to each other in Y-direction. For example, among both ends of the etchback gap EBG in a first lateral direction (X-direction), the main equipotential plane MEP may be adjacent to one end of the etchback gap EBG, and the sub-equipotential plane SEP may be adjacent to the other end of the etchback gap EBG. The main equipotential plane MEP and the sub-equipotential plane SEP may be arranged for the etchback gap EBG to intervene therebetween, and may be connected to each other by the equipotential plating line 122EL extending through the etchback gap EBG.

Each of the plurality of equipotential extension plating lines 122EB may extend from the equipotential plating line 122EL toward a respective one of the etchback openings EBO in the Y-direction, and may be arranged in the etchback gap EBG. In some embodiments, each of two equipotential extension plating lines 122EB may extend from the equipotential plating line 122EL toward one of two adjacent etchback openings EBO. Each of the two equipotential extension plating lines 122EB may extend from the first equipotential plating line 122ELa, may extend along the etchback gap EBG, and may extend toward at least one of adjacent etchback openings EBO in the first lateral direction. For example, two equipotential extension plating lines 122EB may extend from the equipotential plating line 122EL, which is configured to connect the main equipotential plane MEP to the sub-equipotential plane SEP, toward each of two etchback openings EBO defining the etchback gap EBG. For example, the equipotential plating line 122EL and the two equipotential extension plating lines 122EB may be arranged in a ‘+’ shape between the main equipotential plane MEP and the sub-equipotential plane SEP, and may be arranged in the etchback gap EBG. A direction, in which the equipotential plating line 122EL extends, may be perpendicular to a direction in which each of the two equipotential extension plating lines 122EB extends.

Although one end of the equipotential extension plating line 122EB is connected to the equipotential plating line 122EL, the other end of the equipotential extension plating line 122EB may not be connected to other substrate wiring patterns 122. The other end of the equipotential extension plating line 122EB may be at an edge of the etchback opening EBO. The other end of the equipotential extension plating line 122EB may be in contact with the molding layer (refer to 500 in FIG. 1A) filling the etchback opening EBO.

Referring to FIGS. 1B and 2C together, all components may be the same as in FIG. 2B, except for the equipotential extension plating line 122EB.

The equipotential extension plating line 122EBa may extend from the equipotential plating line 122EL extending through (i.e., in) the etchback gap EBG toward one of two etchback openings EBO defining the etchback gap EBG. In some embodiments, one equipotential extension plating line 122EBa may extend from the equipotential plating line 122EL extending through the etchback gap EBG toward one of the two etchback openings EBO defining the etchback gap EBG. One equipotential extension plating line 122EBa may extend from the equipotential plating line 122EL toward one of the two etchback openings defining the etchback gap EBG. The equipotential plating line 122EL may be configured to connect the main equipotential plane MEP to the sub-equipotential plane SEP. For example, the equipotential plating line 122EL and the one equipotential extension plating line 122EBa may be formed in a ‘T’ shape between the main equipotential plane MEP and the sub-equipotential plane SEP, which are adjacent to both ends of the etchback gap EBG. In some embodiments, a direction in which the equipotential plating line 122EL extends may be perpendicular to a direction in which the one equipotential extension plating line 122EBa extends.

Referring to FIGS. 2A to 2C together, the PCB 100 may include a portion having at least one of a structure shown in FIG. 2A, a structure shown in FIG. 2B, and a structure shown in FIG. 2C.

In some embodiments, the PCB 100 may include only one among the structures shown in FIG. 2A, the structure shown in FIG. 2B, and the structure shown in FIG. 2C. For example, the PCB 100 may include a plurality of equipotential plating lines 122EL extending through a plurality of etchback gaps EBG, and the equipotential extension plating line 122EB shown in FIG. 2B or the equipotential extension plating line 122EBa shown in FIG. 2C may not be connected to each of the plurality of equipotential plating lines 122EL.

For example, the PCB 100 may include the plurality of equipotential plating lines 122EL extending through the plurality of etchback gaps EBG, and the two equipotential extension plating lines 122EB shown in FIG. 2B may be connected to each of the plurality of equipotential plating lines 122EL. For example, the PCB 100 may include the plurality of equipotential plating lines 122EL extending through the plurality of etchback gaps EBG, and the equipotential extension plating line 122EBa shown in FIG. 2C may be connected to each of the plurality of equipotential plating lines 122EL.

In some embodiments, the PCB 100 may include at least two structures among the structures shown in FIG. 2A, the structure shown in FIG. 2B, and the structure shown in FIG. 2C.

For example, the PCB 100 may include the plurality of equipotential plating lines 122EL extending through the plurality of etchback gaps EBG, and the equipotential extension plating line 122EB shown in FIG. 2B or the equipotential extension plating line 122EBa shown in FIG. 2C may not be connected to each of some of the plurality of equipotential plating lines 122EL, and the two equipotential extension plating lines 122EB shown in FIG. 2B may be connected to each of the other equipotential plating lines 122EL.

In some embodiments, the PCB 100 may include both the structures shown in FIG. 2A and the structure shown in FIG. 2C. For example, the PCB 100 may include the plurality of equipotential plating lines 122EL extending through the plurality of etchback gaps EBG, the equipotential extension plating line 122EB shown in FIG. 2B or the equipotential extension plating line 122EBa shown in FIG. 2C may not be connected to each of some of the plurality of equipotential plating lines 122EL, and the equipotential extension plating line 122EBa shown in FIG. 2C may be connected to each of other equipotential plating lines 122EL.

In some embodiments, the PCB 100 may include both the portions shown in FIG. 2B and the portion shown in FIG. 2C. For example, the PCB 100 may include the plurality of equipotential plating lines 122EL extending through the plurality of etchback gaps EBG, the equipotential extension plating line 122EB shown in FIG. 2B may be connected to each of some of the plurality of equipotential plating lines 122EL, and the equipotential extension plating line 122EBa shown in FIG. 2C may be connected to each of other equipotential plating lines 122EL.

In some embodiments, the PCB 100 may include a first region having the structure shown in FIG. 2A, a second region having structure shown in FIG. 2B, and a third region having the structure shown in FIG. 2C. In some embodiments, the PCB 100 may include a fourth region having shown in FIG. 2B and a fifth region having the structure shown in FIG. 2C. For example, the PCB 100 may include the plurality of equipotential plating lines 122EL extending through the plurality of etchback gaps EBG. The equipotential extension plating line 122EB shown in FIG. 2B or the equipotential extension plating line 122EBa shown in FIG. 2C may not be connected to each of some of the plurality of equipotential plating lines 122EL, the equipotential extension plating line 122EB shown in FIG. 2B may be connected to each of some others of the plurality of equipotential plating lines 122EL, and the equipotential extension plating line 122EBa shown in FIG. 2C may be connected to each of other equipotential plating lines 122EL.

Referring to FIGS. 1A to 2C together, the PCB 100 may include the main equipotential plane MEP, the sub-equipotential plane SEP. the PCB 100 may include the equipotential plating line 122EL, which may be electrically connected to the upper equipotential pad 122UPE., The equipotential plating line 122EL may electrically connect the main equipotential plane MEP to the sub-equipotential plane SEP and/or may electrically connect the sub-equipotential plane SEP to the upper equipotential pad 122UPE. The main equipotential plane MEP may be electrically connected to the upper equipotential pad 122UPE via some of the equipotential plating line 122EL (and/or the sub-equipotential plane SEP). From among the plurality of equipotential plating lines 122EL, a portion of the equipotential plating line 122EL extending through the etchback gap EBG may electrically connect the main equipotential plane MEP to the sub-equipotential plane SEP, and the equipotential plating line 122EL. From among the plurality of equipotential plating lines 122EL, a portion of the equipotential plating line 122EL not extending through the etchback gap EBG may electrically connect the sub-equipotential plane SEP to the upper equipotential pad 122UPE.

Accordingly, in the PCB 100 according to an embodiment of the inventive concept, an electrical connection path between the main equipotential plane MEP and the upper equipotential pad 122UPE may be shortened. Further, a ratio of an area occupied by an equipotential conductive lines (and/or planes) to all of the upper surface of the PCB 100 may be increased especially due to the sub-equipotential plane SEP electrically connecting the main equipotential plane MEP to the upper equipotential pad 122UPE. Therefore, signal integrity (SI) and power integrity (PI) of the semiconductor package 1 including the PCB 100 may improve, and thus, reliability of the semiconductor package 1 including the PCB 100 may improve.

As shown in the drawings, at least one of the equipotential planes MEP, the plurality of sub-equipotential planes SEP, the equipotential extension plating lines 122EB, the equipotential plating lines 122EL, the signal plating lines 122SL, the upper equipotential pad 122UPE and the upper signal pad 122UPS may be integrally formed in a PCB substrate.

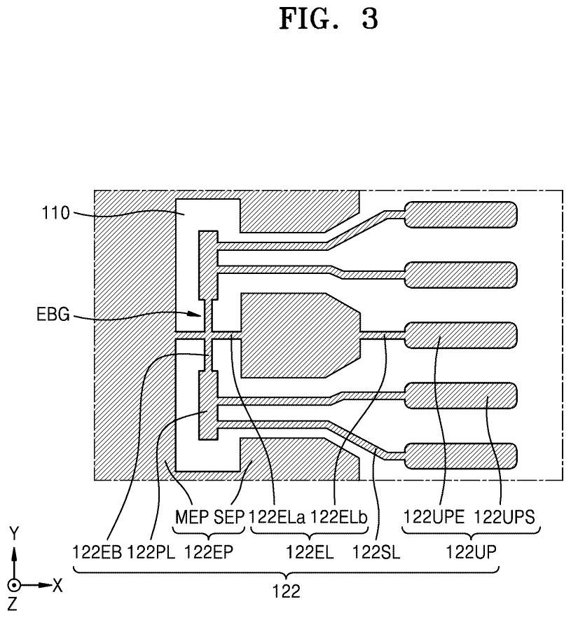

FIGS. 3 to 6 are plan views of a method of manufacturing a PCB, according to an embodiment. Specifically, FIGS. 3 to 6 are plan views showing the upper surface of the PCB 100, which is illustrated in FIGS. 1B and 2B.

Referring to FIG. 3, upper wiring patterns, which are substrate wiring patterns 122, may be formed on an upper surface of a substrate base 110. The upper wiring patterns may include a plurality of plating power inlet patterns 122PL, a plurality of equipotential planes 122EP (with only one being shown in FIG. 3), a plurality of equipotential plating lines 122EL, a plurality of signal plating lines 122SL, and a plurality of upper connection pads 122UP. The plurality of plating power inlet patterns 122PL, the plurality of equipotential planes 122EP, the plurality of equipotential plating lines 122EL, the plurality of signal plating lines 122SL, and the plurality of upper connection pads 122UP may be integrally connected to each other and formed in the same process. The upper wiring patterns may be formed using copper (Cu) or a Cu-containing alloy. The upper wiring patterns may include or be formed of ED copper foils, RA copper foils, ultrathin copper foils, sputtered copper, or copper alloys.

At least one of the equipotential plating line 122EL, the signal plating line 122SL, and an equipotential extension plating line 122EB may be connected to each of the plurality of plating power inlet patterns 122PL. For example, the signal plating line 122SL and the equipotential extension plating line 122EB may be connected to each of the plurality of plating power inlet patterns 122PL. The plating power inlet pattern 122PL may have a rectangular planar shape. The plating power inlet pattern 122PL may have a lateral width of about 50 μm in a minor axis direction (X-direction) and extend in a major axis direction (Y-direction).

Each upper connection pad of a first set of the plurality of upper connection pads 122UP may be electrically connected to a respective one of the plurality of equipotential plating lines 122EL. Each upper connection pad of a second set of the plurality of upper connection pads 122UP may be connected to one of the plurality of signal plating lines 122SL. The plurality of upper connection pads 122UP may include a plurality of upper signal pads 122UPS and at least one upper equipotential pad 122UPE. The plurality of signal plating lines 122SL may be connected to the plurality of upper signal pads 122UPS. The plurality of equipotential plating lines 122EL may be connected to the at least one upper equipotential pad 122UPE.

The equipotential plane 122EP may include at least one main equipotential plane MEP and a plurality of sub-equipotential planes SEP. At least two equipotential plating lines 122EL may be connected to each equipotential plane 122EP. In some embodiments, the main equipotential plane MEP may be connected to each two sub-equipotential plane SEP through at least two equipotential plating lines 122EL. The at least two equipotential plating lines 122EL may be connected to the sub-equipotential plane SEP. From among the at least two equipotential plating lines 122EL connected to the sub-equipotential plane SEP, the main equipotential plane MEP may be connected to at least one equipotential plating line 122EL, and an upper equipotential pad 122UPE may be connected to another equipotential plating line 122EL.

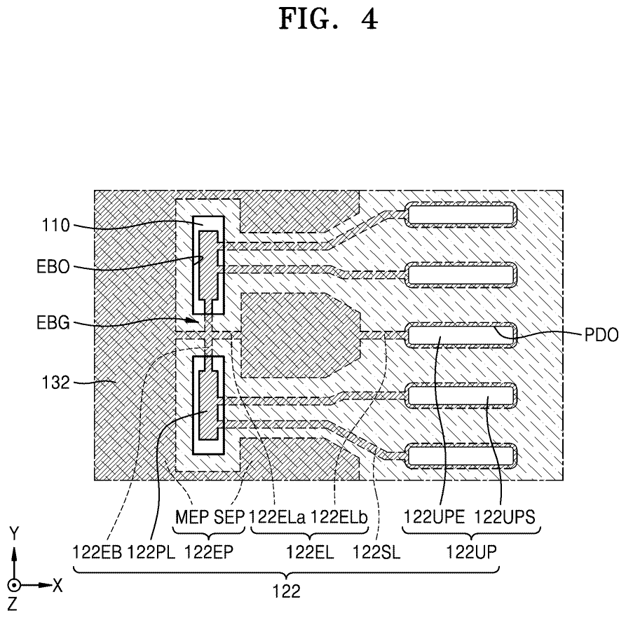

Referring to FIG. 4, an upper solder resist layer 132 covering portions of the upper wiring patterns may be formed on the upper surface of the substrate base 110. The upper solder resist layer 132 may have a plurality of upper pad openings PDO and a plurality of etchback openings EBO. The plurality of upper connection pads 122UP may be disposed at bottom portions of the plurality of upper pad openings PDO. A portion of the substrate base 110 and the plating power inlet pattern 122PL may be at a bottom portion of each of the plurality of etchback openings EBO.

In some embodiments, a planar shape of the upper pad opening PDO may be substantially the same as a planar shape of the upper connection pad 122UP. A lateral area of the upper pad opening PDO may be less than a lateral area of the upper connection pad 122UP. A portion of the upper surface of the upper connection pad 122UP may be disposed adjacent to the bottom portion of the upper pad opening PDO to surround the upper pad opening PDO in a view from above. In the view from above, another portion of the upper surface of the upper connection pad 122UP, which is adjacent to an edge of the upper connection pad 122UP, may be disposed within the upper pad opening PDO. In a view from above, the upper pad opening PDO may entirely overlap a corresponding one of the upper connection pads 122UP.

A lateral width of the etchback opening EBO in the X-direction may be greater than a lateral width of the plating power inlet pattern 122PL in the X-direction. An upper surface of the plating power inlet pattern 122PL, a portion of the equipotential extension plating line 122EB adjacent to the plating power inlet pattern 122PL, a portion of the signal plating line 122SL adjacent to the plating power inlet pattern 122PL, and a portion of the upper surface of the substrate base 110 adjacent to the plating power inlet pattern 122PL may be disposed at the bottom portion of the etchback opening EBO.

In a view from above, an edge of the etchback opening EBO may be apart from an edge of the plating power inlet pattern 122PL. In the view from above, the edge of the etchback opening EBO may be a distance of about 40 μm to about 50 μm apart from the edge of the plating power inlet pattern 122PL.

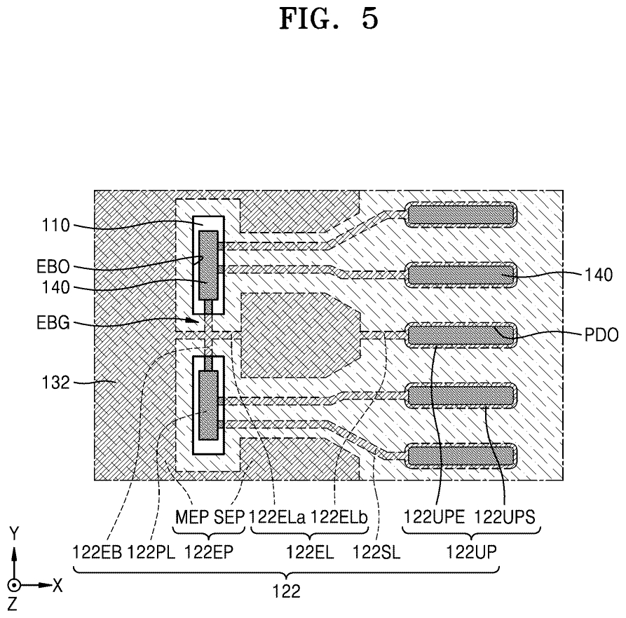

Referring to FIG. 5, a plurality of upper pad layers 140 may be formed on upper surfaces of portions of the substrate wiring patterns 122, which are inside (or exposed by) the plurality of upper pad openings PDO and the plurality of etchback openings EBO by an electroplating process. The plurality of upper pad layers 140 may be formed by applying a plating voltage through the plating power inlet pattern 122PL. The plurality of upper pad layers 140 may be formed on portions of the substrate wiring patterns 122, which are not covered by the upper solder resist layer 132. For example, the plurality of upper pad layers 140 may be formed to cover portions of the plurality of upper connection pads 122UP inside (or exposed by) the plurality of upper pad openings PDO, the upper surface of the plating power inlet pattern 122PL located inside (or exposed by) each of the plurality of etchback openings EBO, a portion of the equipotential extension plating line 122EB connected and adjacent to the plating power inlet pattern 122PL, and an upper surface of a portion of the signal plating line 122SL connected and adjacent to the plating power inlet pattern 122PL. The portions of the substrate wiring patterns 122, which are not covered by the upper solder resist layer 132, may function as seed layers for forming the plurality of upper pad layers 140 during the electroplating process.

Each of the plurality of upper pad layers 140 may be formed to include or be formed of a metal, such as nickel (Ni), gold (Au), and copper (Cu). In some embodiments, each of the plurality of upper pad layers 140 may be formed to have a composite layer of a first layer including nickel (Ni) and a second layer including gold (Au).

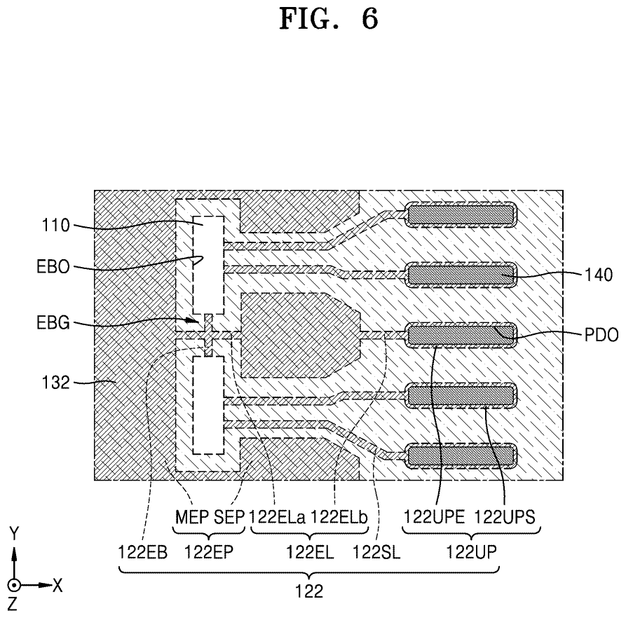

Referring to FIGS. 5 and 6 together, the portions of the substrate wiring patterns 122 located inside the plurality of etchback openings EBO and the upper pad layers 140 covering the portions of the substrate wiring patterns 122 located in the plurality of etchback openings EBO may be removed such that only portions of the substrate base 110 are exposed at the bottom portion of each of the plurality of etchback openings EBO. Thus, the PCB 100 shown in FIG. 1B may be formed.

Each of the upper pad layers 140, which is not removed but remains, may cover at least a portion of the upper surface of the upper connection pads 122UP. The substrate wiring patterns 122, which are not removed but remain, may include the plurality of equipotential planes 122EP, a portion of the plurality of equipotential extension plating lines 122EB, the plurality of equipotential plating lines 122EL, a portion of the plurality of signal plating lines 122SL, and the plurality of upper connection pads 122UP. The plurality of upper connection pads 122UP may include a plurality of upper signal pads 122UPS and at least one upper equipotential pad 122UPE. The equipotential plane 122EP may include the main equipotential plane MEP and the sub-equipotential planes SEP. Some of the signal plating lines 122SL and some of the equipotential extension plating lines 122EB (or 122Eba) may have respective ends which are adjacent to corresponding ones of the plurality of etchback openings EBO, because the removing the substrate wiring patterns 122 and the upper pad layers 140 may be performed by using the upper solder resist layer 132 as a mask defining the etchback openings EBO. Similarly, a portion of some of the first equipotential plating line 122ELa may be adjacent to a corresponding one of the plurality of etchback openings EBO. Further, the ends adjacent to the etchback openings EBO of the signal plating lines 122SL and the equipotential extension plating lines 122EB (or 122Eba) may have their side edges substantially aligned with the vertical walls of the etchback openings EBO (e.g., aligned with sidewalls of the upper solder resist layer 132). Similarly, the adjacent portion of the first equipotential plating line 122ELa may have its side edge which is substantially aligned with the vertical walls of the etchback openings EBO (e.g., aligned with sidewalls of the upper solder resist layer 132).

The term “substantially aligned” as used herein encompasses variations that may occur, for example, due to manufacturing processes. For example, during the removal of the substrate wiring patterns 122 and the upper pad layers 140, the wiring patterns may be removed in both vertical and lateral direction, thereby inducing recesses of the adjacent features of the substrate wiring patterns in the lateral direction. The amount of lateral recess from the sidewalls of the etchback openings EBO may be substantially the same for each sidewall. It should be noted that term “substantially aligned” is interpreted to encompass this lateral recess. As a result of the etchback process, etchback openings EBO may be formed and etchback gaps EBG, which may be described as solder resist-covered regions laterally between adjacent etchback openings EBO, may also be formed.

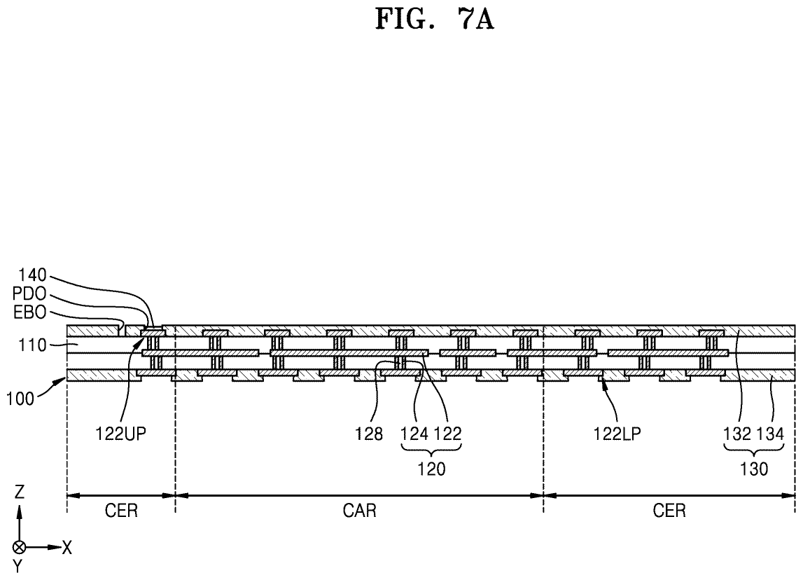

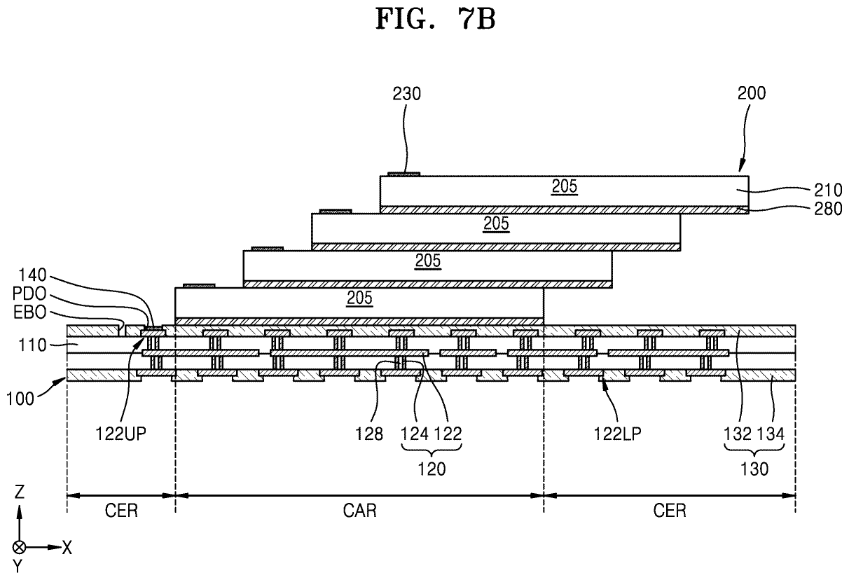

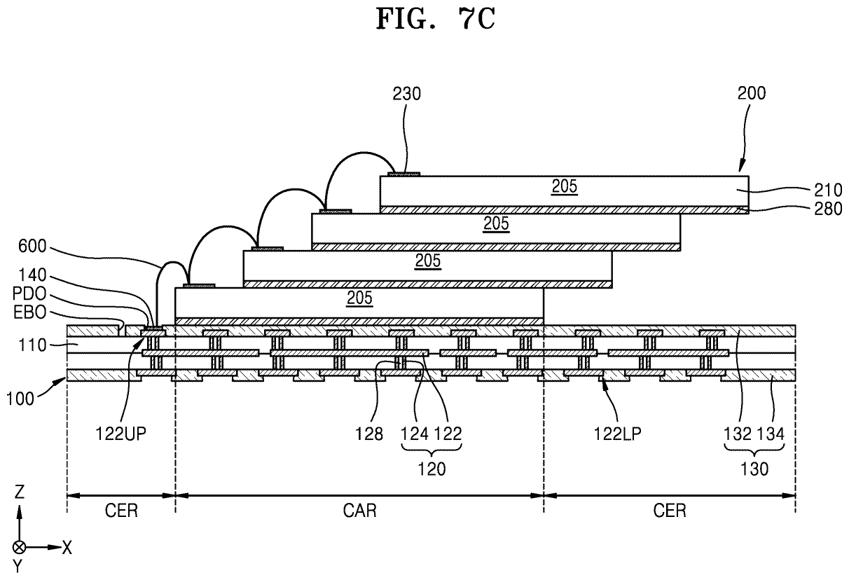

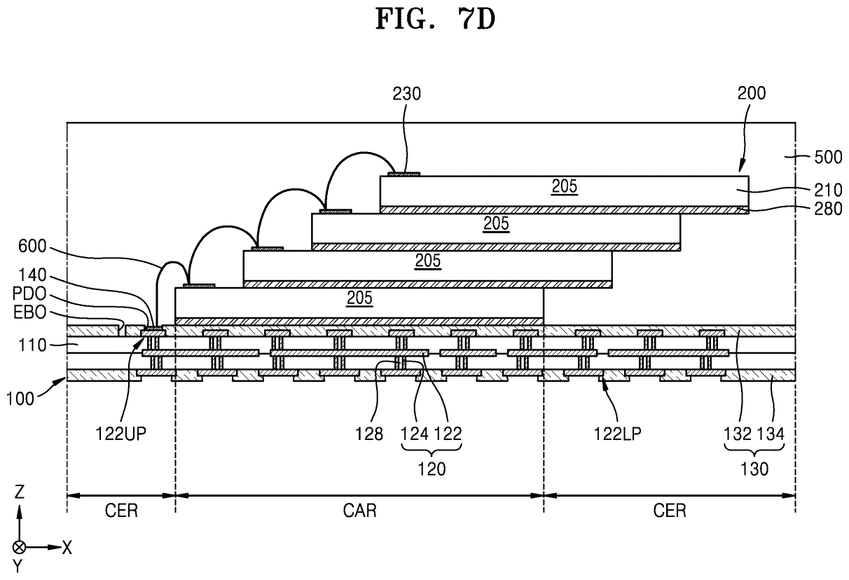

FIGS. 7A to 7D are cross-sectional views of a method of manufacturing a semiconductor package, according to an embodiment.

Referring to FIG. 7A, a PCB 100 may be provided. The PCB 100 may have a structure described earlier and manufactured by the method described earlier. The PCB 100 may have a chip adhesion region CAR and a chip peripheral region CER surrounding the chip adhesion region CAR. The PCB 100 may include at least one substrate base 110, a substrate wiring structure 120, and a solder resist layer 130 covering an upper surface and a lower surface of the at least one substrate base 110. The solder resist layer 130 may include an upper solder resist layer 132 covering the upper surface of the at least one substrate base 110 and a lower solder resist layer 134 covering the lower surface of the at least one substrate base 110. Some of substrate wiring patterns 122 located on the upper surface of the at least one substrate base 110 may be a plurality of upper connection pads 122UP. Some of substrate wiring patterns 122 located on the lower surface of the at least one substrate base 110 may be a plurality of lower connection pads 122LP.

The upper solder resist layer 132 may have a plurality of upper pad openings PDO and a plurality of etchback openings EBO. In some embodiments of the invention, the plurality of upper connection pads 122UP may be disposed at bottom portions of the plurality of upper pad openings PDO. In some embodiments of the invention, a portion of the substrate base 110 may be exposed by a bottom portion of each of the plurality of etchback openings EBO. A plurality of upper pad layers 140 may be formed on the plurality of upper connection pads 122UP. The plurality of upper pad layers 140 may cover the plurality of upper connection pads 122UP and fill at least portions of the plurality of upper pad openings PDO.

Referring to FIG. 7B, a plurality of semiconductor chips 200 may be stacked on the PCB 100. The plurality of semiconductor chips 200 may be sequentially stacked on the PCB 100 in a vertical direction (Z-direction). Each of the plurality of semiconductor chips 200 may include a semiconductor substrate 210 having an active surface and an inactive surface that is opposite to the active surface, a semiconductor device 205 formed on the active surface of the semiconductor substrate 210, and a plurality of chip pads 230 respectively on upper surfaces of the plurality of semiconductor chips 200. Each of the plurality of semiconductor chips 200 may be stacked on the PCB 100 such that the inactive surface of the semiconductor substrate 210 faces downward (i.e., toward the PCB 100).

In some embodiments, the plurality of semiconductor chips 200 may be stacked in a staircase manner and arranged at intervals in a lateral direction (X-direction or Y-direction). For example, a lowermost one of the plurality of semiconductor chips 200 may be aligned with the chip adhesion region CAR in the vertical direction (Z-direction). In some embodiments, the plurality of semiconductor chips 200 may be stacked in a staircase manner at intervals in a direction along one side of a rectangular planar shape of at least one of the semiconductor chips. In some embodiments, the plurality of semiconductor chips 200 may be stacked in a staircase manner at intervals in a direction (X-Y-direction) along a diagonal line of a rectangular planar shape of at least one of the semiconductor chips. In some embodiments, some of the plurality of semiconductor chips 200 may be stacked in a staircase manner at intervals in one direction, and some others of the plurality of semiconductor chips 200 may be stacked on the some semiconductor chips 200 in a staircase manner in a direction opposite to the one direction. In some embodiments, the plurality of semiconductor chips 200 may be stacked and aligned with each other in the vertical direction (Z-direction). For example, each of the plurality of semiconductor chips 200 may be aligned with the chip adhesion region CAR in the vertical direction (Z-direction).

The plurality of semiconductor chips 200 may be respectively adhered onto lower structures with a plurality of die-bonding films 280 adhered to lower surfaces of the semiconductor chips 200 therebetween. For example, the lowermost one of the plurality of semiconductor chips 200 may be adhered onto the chip adhesion region CAR of the PCB 100 with the die-bonding film 280 therebetween, and each of other semiconductor chips 200 may be adhered onto another semiconductor chip 200 located thereunder with the die-bonding film 280 therebetween.

Referring to FIG. 7C, a plurality of bonding wires 600 may be formed to electrically connect the PCB 100 to the plurality of semiconductor chips 200. The plurality of bonding wires 600 may connect the plurality of chip pads 230 to the plurality of upper pad layers 140 covering the plurality of upper connection pads 122UP. In some embodiments, after the plurality of chip pads 230 of the respective semiconductor chips 200 are sequentially connected from the plurality of chip pads 230 of an uppermost one of the semiconductor chips 200 to the plurality of chip pads 230 of the lowermost one of the semiconductor chips 200, the plurality of bonding wires 600 may be formed to connect the plurality of chip pads 230 of the lowermost one of the semiconductor chips 200 to the plurality of upper pad layers 140 covering the plurality of upper connection pads 122UP. In some other embodiments, the plurality of bonding wires 600 may be formed to connect the plurality of chip pads 230 of the plurality of semiconductor chips 200 with the plurality of upper pad layers 140 covering the plurality of upper connection pads 122UP.

Referring to FIG. 7D, a molding layer 500 may be formed to cover an upper surface of the PCB 100 and surround the plurality of semiconductor chips 200 and the plurality of bonding wires 600. The molding layer 500 may be formed to fill the plurality of etchback openings EBO. The molding layer 500 may fill the plurality of etchback openings EBO and be formed to cover portions of the substrate base 110 which are exposed by the bottom portion of the etchback opening EBO. When the plurality of upper pad layers 140 do not entirely fill the plurality of upper pad openings PDO, the molding layer 500 may be formed to fill the plurality of upper pad openings PDO. The molding layer 500 may fill the plurality of upper pad openings PDO and be formed to surround the plurality of bonding wires 600 and cover the plurality of upper pad layers 140.

Subsequently, the plurality of package connection terminals 150 shown in FIG. 1A may be adhered to a lower surface of the PCB 100, and thus, a semiconductor package 1 may be formed. The plurality of package connection terminals 150 may be adhered to the plurality of lower connection pads 122LP.

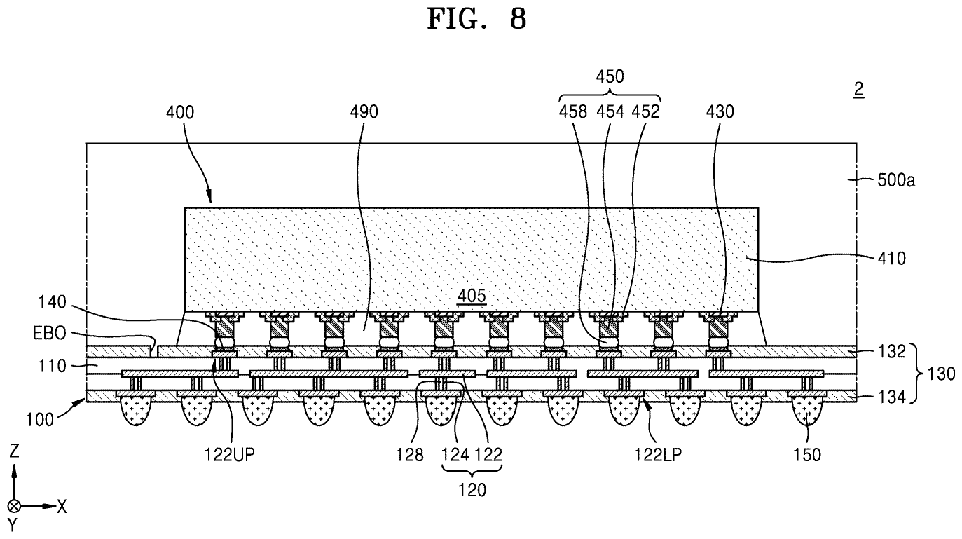

FIG. 8 is a cross-sectional view of a semiconductor package 2 according to embodiments.

Referring to FIG. 8, the semiconductor package 2 may include a PCB 100, at least one semiconductor chip 400, and a molding layer 500a. The at least one semiconductor chip 400 may be adhered onto the PCB 100. The molding layer 500a may surround the at least one semiconductor chip 400 on the PCB 100. An electromagnetic shielding layer 900a may cover the PCB 100 and the molding layer 500a.

For example, the PCB 100 may be a both-sided PCB or a multilayered PCB. The PCB 100 may include at least one substrate base 110 and a substrate wiring structure 120. The PCB 100 may substantially be the same as the PCB 100 shown in FIG. 1, and thus, repeated descriptions thereof may be omitted. The PCB 100 may include the at least one substrate base 110, the substrate wiring structure 120, and a solder resist layer 130 covering an upper surface and a lower surface of the at least one substrate base 110. The solder resist layer 130 may include an upper solder resist layer 132 covering the upper surface of the at least one substrate base 110 and a lower solder resist layer 134 covering the lower surface of the at least one substrate base 110. Some of substrate wiring patterns 122 located on the upper surface of the at least one substrate base 110 may be a plurality of upper connection pads 122UP. Some of the substrate wiring patterns 122 located on the lower surface of the at least one substrate base 110 may be a plurality of lower connection pads 122LP. The upper solder resist layer 132 may have a plurality of upper pad openings PDO and a plurality of etchback openings EBO. In some embodiments of the invention, the plurality of upper connection pads 122UP may be disposed at bottom portions of the plurality of upper pad openings PDO. In some embodiments of the invention, a portion of the substrate base 110 may be exposed by a bottom portion of each of the plurality of etchback openings EBO. A plurality of upper pad layers 140 may be formed on the plurality of upper connection pads 122UP. The plurality of upper pad layers 140 may cover the plurality of upper connection pads 122UP and fill at least portions of the plurality of upper pad openings PDO. A plurality of chip terminals 450 may be adhered to the plurality of upper pad layers 140 covering the plurality of upper connection pads 122UP. A plurality of package connection terminals 150 may be adhered to the plurality of lower connection pads 122LP.

The at least one semiconductor chip 400 may include a semiconductor substrate 410. The semiconductor substrate 410 may substantially include the same material as the semiconductor substrate 210 shown in FIG. 1. For example, the semiconductor substrate 410 may include a semiconductor material, such as a Group IV semiconductor material, a Group III-V semiconductor material, a Group II-VI semiconductor material, or a Group II-VI oxide semiconductor material. For example, the semiconductor substrate 410 may include silicon. The semiconductor substrate 410 may have an active surface and an inactive surface, which are opposite to each other.

A semiconductor device 405 may be formed on the active surface of the semiconductor substrate 410. The semiconductor device 405 may include a logic device or a memory device. The memory device may include a volatile memory device or a non-volatile memory device. In some embodiments, the semiconductor chip 400 may include a logic device. For example, the semiconductor chip 400 may be a central processing unit (CPU) chip, a graphics processing unit (GPU) chip, or an application processor (AP) chip. In some embodiments, the semiconductor chip 400 may be a memory semiconductor chip including a memory device. For example, the memory device may be a non-volatile memory device, such as flash memory, PRAM, MRAM, FRAM, and RRAM. The flash memory may be, for example NAND flash memory or V-NAND) flash memory. In some embodiments, the memory device may be a volatile memory device, such as dynamic RAM (DRAM) or static RAM (SRAM). In some other embodiments, when the semiconductor package 2 includes a plurality of semiconductor chips 400, at least one of the plurality of semiconductor chips 400 may be a CPU chip, a GPU chip, or an AP chip, and at least one of the other semiconductor chips 400 may be a memory semiconductor chip including a memory device.

The at least one semiconductor chip 400 may include a plurality of chip pads 430 on the active surface of the semiconductor substrate 410. For example, the semiconductor chip 400 may be adhered onto the PCB 100 such that the plurality of chip pads 430 face the PCB 100. The plurality of chip terminals 450 may be between the plurality of chip pads 430 and the plurality of upper connection pads 122UP and electrically connect the semiconductor chip 400 to the PCB 100. The plurality of chip pads 430 may be electrically connected to the semiconductor device 405.

The semiconductor package 2 may include the molding layer 500a, which covers an upper surface of the PCB 100 on the PCB 100 and surrounds the semiconductor chip 400. For example, the molding layer 500a may be a molding member including an EMC. The molding layer 500a may be formed to fill the plurality of etchback openings EBO. The molding layer 500a may fill the plurality of etchback openings EBO and be formed to cover portions of the substrate base 110 which are exposed by the bottom portion of the etchback opening EBO.

In some embodiments, the molding layer 500a may cover a side surface and an upper surface of the semiconductor chip 400. In another embodiment, the molding layer 500a may cover the side surface of the semiconductor chip 400 without covering the upper surface of the semiconductor chip 400. When the molding layer 500a does not cover the upper surface of the semiconductor chip 400, the semiconductor package 2 may further include a heat-dissipation member covering the upper surface of the semiconductor chip 400. The heat-dissipation member may include a heat-dissipation plate, such as a heat slug or a heat sink. In addition, the semiconductor package 2 may further include a thermal interface material (TIM) between the heat-dissipation member and the semiconductor chip 400. The TIM may include paste or a film.

In some embodiments, an underfill layer 490 surrounding the plurality of chip terminals 450 and filling a space between the PCB 100 and the semiconductor chip 400 may be between the PCB 100 and the semiconductor chip 400. The underfill layer 490 may include a resin. For example, the underfill layer 490 may be formed of an epoxy resin by using a capillary under-fill method. In some embodiments, the underfill layer 490 may be mixed with filler, and the filler may include, for example, silica. In some other embodiments, the semiconductor package 2 may not include the underfill layer 490, and the molding layer 500a may be formed using a molded underfill (MUF), which surrounds the plurality of chip terminals 450 and is between the PCB 100 and the semiconductor chip 400.

While the inventive concept has been particularly shown and described with reference to embodiments thereof, it will be understood that various changes in form and details may be made therein without departing from the spirit and scope of the following claims.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

What is claimed is:

1. A printed circuit board comprising:
a substrate base;
a plurality of upper wiring patterns on an upper surface of the substrate base, the plurality of upper wiring patterns comprising:
a first equipotential plane, wherein the first equipotential plane includes a first main equipotential plane and a plurality of sub-equipotential planes;
a first equipotential plating line;
a plurality of signal plating lines; and
a plurality of upper connection pads;
a plurality of upper pad layers covering at least portions of the plurality of upper connection pads; and
an upper solder resist layer covering a portion of the upper surface of the substrate base and portions of the plurality of upper wiring patterns,
wherein the upper solder resist layer comprises:
a plurality of etchback openings arranged in a column in a first lateral direction, bottom portions of the plurality of etchback openings exposing portions of the upper surface of the substrate base; and
an etchback gap disposed between two etchback openings, which are adjacent to each other in the first lateral direction, and
wherein the first equipotential plating line extends through the etchback gap and connects the first main equipotential plane to one of the plurality of sub-equipotential planes.

2. The printed circuit board of claim 1, the printed circuit board further comprising a second equipotential plating line, wherein:
the plurality of upper connection pads includes a first upper connection pad and a plurality of second upper connection pads,
the plurality of second upper connection pads are connected to the plurality of signal plating lines, and
the first upper connection pad is connected to the second equipotential plating line.

3. The printed circuit board of claim 2, wherein:
one end of each of the plurality of signal plating lines is connected to one of plurality of second upper connection pads,
another end of each of the plurality of signal plating lines has a side edge adjacent to a corresponding one of the plurality of etchback openings, and
the side edge is substantially aligned with a vertical wall of the corresponding one of the plurality of etchback openings.

4. The printed circuit board of claim 2, wherein one end of the second equipotential plating line is connected to the first upper connection pad, and another end of the second equipotential plating line is connected to one of the plurality of sub-equipotential planes.

5. The printed circuit board of claim 1, wherein the plurality of etchback openings are between the at least one main equipotential plane and the plurality of sub-equipotential planes in a second lateral direction that is perpendicular to the first lateral direction, and
the plurality of sub-equipotential planes are between the plurality of etchback openings and the plurality of upper connection pads in the second lateral direction.

6. The printed circuit board of claim 5, wherein the at least one main equipotential plane is adjacent to one end of the etchback gap in the second lateral direction, and
one of the plurality of sub-equipotential planes is adjacent to another end of the etchback gap in the second lateral direction.

7. The printed circuit board of claim 1, wherein the plurality of upper wiring patterns further comprise at least one equipotential extension plating line on the upper surface of the substrate base, and
the at least one equipotential extension plating line extends:
from the first equipotential plating line,
through the etchback gap, and
toward at least one of adjacent etchback openings in the first lateral direction.

8. The printed circuit board of claim 7, wherein:
one end of the at least one equipotential extension plating line is connected to the first equipotential plating line,
another end of the at least one equipotential extension plating line has a side edge adjacent to a corresponding one of the plurality of etchback openings, and
the side edge is substantially aligned with a vertical wall of the corresponding one of the plurality of etchback openings.

9. The printed circuit board of claim 7, wherein the at least one equipotential extension plating line comprises first and second equipotential extension plating lines, and
each of the first and second equipotential extension plating lines extends:
from the first equipotential plating line,
along the etchback gap, and
toward at least one of adjacent etchback openings in the first lateral direction.

10. The printed circuit board of claim 1, further comprising a plurality of lower connection pads on a lower surface of the substrate base, wherein
the printed circuit board further comprises a plurality of via patterns configured to electrically connect the plurality of upper connection pads to the plurality of lower connection pads,
the plurality of via patterns pass through at least a portion of the substrate base, and
at least one of the plurality of via patterns is connected to a lower surface of each of the plurality of upper connection pads.

11. A printed circuit board comprising:
a substrate base having a chip adhesion region and a chip peripheral region surrounding the chip adhesion region;
a plurality of substrate wiring patterns comprising:
a first equipotential plane comprising a first main equipotential plane and a plurality of sub-equipotential planes;
a plurality of equipotential plating lines;
a plurality of signal plating lines;
a plurality of upper connection pads on an upper surface of the substrate base; and
a plurality of lower connection pads on a lower surface of the substrate base;
a plurality of via patterns configured to electrically connect the plurality of upper connection pads to the plurality of lower connection pads, the plurality of via patterns passing through at least a portion of the substrate base;
a plurality of upper pad layers covering at least portions of the plurality of upper connection pads;
an upper solder resist layer on the plurality of substrate wiring patterns and the upper surface of the substrate base, the upper solder resist layer comprising:
a plurality of etchback openings arranged in a column in a first lateral direction; and
a plurality of upper pad openings arranged in a column in the first lateral direction; and
a lower solder resist layer on the plurality of substrate wiring patterns and the lower surface of the substrate base, the lower solder resist layer exposing at least portions of the plurality of lower connection pads,
wherein:
portions of the upper surface of the substrate base are exposed by bottom portions of the plurality of etchback openings,
at least portions of the plurality of upper connection pads covered by the plurality of upper pad layers are disposed at bottom portions of the plurality of upper pad openings,
at least one of the plurality of equipotential plating lines extends through an etchback gap and connects the at least one main equipotential plane to one of the plurality of sub-equipotential planes,
the plurality of upper connection pads include a first upper connection pad and a plurality of second upper connection pads,
one end of each of the plurality of signal plating lines is connected to a respective connection pad of the plurality of second upper connection pads, and
one end of at least one other of the plurality of equipotential plating lines is connected to the first upper connection pad.

12. The printed circuit board of claim 11, wherein the first main equipotential plane, the plurality of etchback openings, the plurality of sub-equipotential planes, and the plurality of upper connection pads are sequentially arranged in a second lateral direction that is perpendicular to the first lateral direction.

13. The printed circuit board of claim 12, wherein, in the second lateral direction, the chip adhesion region is a first separation distance apart from the plurality of upper connection pads, the plurality of upper connection pads are a second separation distance apart from the plurality of etchback openings, and the plurality of etchback openings are a third separation distance apart from an edge of the substrate base, and
the second separation distance is equal to or less than the first separation distance, and the third separation distance is greater than each of the first separation distance and the second separation distance.

14. The printed circuit board of claim 11, wherein the first main equipotential plane is adjacent to one end of the etchback gap in a second lateral direction that is perpendicular to the first lateral direction, and
one of the plurality of sub-equipotential planes is adjacent to another end of the etchback gap in the second lateral direction.

15. The printed circuit board of claim 11, wherein another end of each of the plurality of signal plating lines has a side edge adjacent to a corresponding one of the plurality of etchback openings, and
the side edge is substantially aligned with a vertical wall of the corresponding one of the plurality of etchback openings.

16. The printed circuit board of claim 11, wherein another end of the at least one other of the plurality of equipotential plating lines is connected to one of the plurality of sub-equipotential planes.

17. A semiconductor package comprising:
a printed circuit board;
at least one semiconductor chip on the printed circuit board, the at least one semiconductor chip comprising a plurality of chip pads;
a plurality of bonding wires connected to the plurality of chip pads; and
a molding layer covering the printed circuit board and surrounding the at least one semiconductor chip and the plurality of bonding wires,
wherein the printed circuit board comprises:
a substrate base having a chip adhesion region to which the at least one semiconductor chip is adhered and a chip peripheral region surrounding the chip adhesion region;
a plurality of substrate wiring patterns comprising:
a first equipotential plane comprising a first main equipotential plane and a plurality of sub-equipotential planes;
a plurality of equipotential plating lines;
a plurality of signal plating lines; and
a plurality of upper connection pads on an upper surface of the substrate base;
a plurality of lower connection pads on a lower surface of the substrate base;
a plurality of upper pad layers covering at least portions of the plurality of upper connection pads and connected to the plurality of bonding wires;
an upper solder resist layer on the plurality of substrate wiring patterns and the upper surface of the substrate base, the upper solder resist layer comprising:
a plurality of etchback openings arranged in a column in a first lateral direction; and
a plurality of upper pad openings arranged in a column in the first lateral direction,
wherein portions of the upper surface of the substrate base are exposed by bottom portions of the plurality of etchback openings,
wherein at least the portions of the plurality of upper connection pads covered by the plurality of upper pad layers are disposed at bottom portions of the plurality of upper pad openings,
wherein at least one of the plurality of equipotential plating lines extends along an etchback gap and connects the first main equipotential plane and one of the plurality of sub-equipotential planes, which are adjacent to opposite ends of the etchback gap in a second lateral direction,
wherein the second lateral direction is perpendicular to the first lateral direction, and
wherein the plurality of etchback openings are filled by the molding layer.

18. The semiconductor package of claim 17, wherein one end of each of the plurality of signal plating lines is connected to one of the plurality of upper connection pads, and
another end of each of the plurality of signal plating lines is in contact with the molding layer filling the plurality of etchback openings.

19. The semiconductor package of claim 17, wherein one end of each of the plurality of equipotential plating lines is connected to one of the plurality of sub-equipotential planes, and
another end of each of the plurality of equipotential plating lines is connected to at least one other of the plurality of upper connection pads or the at least one main equipotential plane.

20. The semiconductor package of claim 17, wherein each of the plurality of equipotential plating lines and the plurality of signal plating lines has a lateral width of about 20 μm to about 40 μm, and
a gap width of the etchback gap is greater than three times a lateral width of at least one of the plurality of equipotential plating lines extending along the etchback gap and less than five times the lateral width of the at least one of the plurality of equipotential plating lines extending along the etchback gap.
